(19) United States
(12) Patent Application Publication
(10) Pub. No.: US 2026/0331442 A1
(43) Pub. Date: Oct. 22, 2026

(54) PLASMA PROCESSING APPARATUS, PREDICTION METHOD, PREDICTION PROGRAM, AND INFORMATION PROCESSING APPARATUS

(71) Applicant: Tokyo Electron Limited, Tokyo (JP)

(72) Inventor: Masaharu OYA, Miyagi (JP)

(73) Assignee: Tokyo Electron Limited, Tokyo (JP)

(21) Appl. No.: 19/699,498

(22) Filed: Jun. 5, 2026

Related U.S. Application Data
(63) Continuation of application No. PCT/JP2024/044140, filed on Dec. 13, 2024.

(30) Foreign Application Priority Data
Dec. 27, 2023 (JP) 2023-220548

(51) Int. Cl. H01J 37/32

(52) U.S. Cl. CPC H01J 37/32724; H01J 2237/002; H01J 2237/334

(57) ABSTRACT

An acquisition unit periodically acquires a temperature of a stage on which a substrate is placed, a temperature of a cooling mechanism provided in the stage and configured to cool the stage, and an amount of heat generated by a heating mechanism provided between a placement surface of the stage on which the substrate is placed and the cooling mechanism and configured to heat the stage. A prediction unit predicts an amount of heat input flowing from the plasma to the substrate using a calculation formula based on the amount of heat generated by the heating mechanism, the temperature of the stage, and the temperature of the cooling mechanism that are acquired, a first-order time derivative of the temperature of the stage, and a first or higher-order time derivative of the temperature of the cooling mechanism, in which the calculation formula predicts an amount of heat input flowing from the plasma to the substrate based on the amount of heat generated by the heating mechanism, the temperature of the stage, the temperature of the cooling mechanism, the first-order time derivative of the temperature of the stage, and the first or higher-order time derivative of the temperature of the cooling mechanism.

### CROSS-REFERENCE TO RELATED APPLICATIONS

This application is a continuation of International Application No. PCT/JP2024/044140, filed on Dec. 13, 2024 which claims the benefit of priority of the prior Japanese Patent Application No. 2023-220548, filed on Dec. 27, 2023, the entire contents of which are incorporated herein by reference.

### FIELD

The present disclosure relates to a plasma processing apparatus, a prediction method, a prediction program, and an information processing apparatus.

### BACKGROUND

Japanese Laid-open Patent Publication No. 2008-177285 discloses “a plasma processing apparatus including: a processing chamber to be depressurized and evacuated inside; a sample stage provided in the processing chamber and having a sample placement surface on which a substrate to be processed is disposed; a plasma generating device for generating plasma in the processing chamber; a heat transfer gas supply system for supplying heat transfer gas to the sample placement surface; and a coolant channel provided inside the sample stage and through which a coolant circulates, in which the sample stage includes a heater layer provided between the sample placement surface and the coolant channel, the heater layer is formed so as to be divided into a plurality of regions in a radial direction of the sample placement surface, and the plasma processing apparatus further includes: a temperature monitor provided at a position near the heater layer in the sample stage and corresponding to each of the division regions of the heater layer; and a temperature control device for estimating a temperature of a position corresponding to each of the division regions of the substrate to be processed placed on the sample placement surface based on temperature information from each of the temperature monitors and controlling power supply to each of the division regions of the heater layer according to an estimated temperature value”.

The present disclosure provides a technique for measuring an amount of heat input flowing from plasma to a substrate.

### SUMMARY

In an embodiment of a present disclosure, a plasma processing apparatus includes: a stage on which a substrate is placed; a chamber in which the stage is provided and plasma is generated to perform plasma processing on the substrate placed on the stage; a cooling mechanism provided in the stage and configured to cool the stage; a heating mechanism provided between a placement surface of the stage on which the substrate is placed and the cooling mechanism and configured to control an amount of heat generated and to heat the stage; a measurement unit configured to measure a temperature of the stage; an acquisition unit configured to periodically acquire an amount of heat generated by the heating mechanism, a temperature of the stage, and a temperature of the cooling mechanism; and a prediction unit configured to predict an amount of heat input flowing from the plasma to the substrate using a calculation formula based on the amount of heat generated by the heating mechanism, the temperature of the stage, and the temperature of the cooling mechanism that are acquired by the acquisition unit, a first-order time derivative of the temperature of the stage, and a first or higher-order time derivative of the temperature of the cooling mechanism, in which the calculation formula predicts an amount of heat input flowing from the plasma to the substrate based on the amount of heat generated by the heating mechanism, the temperature of the stage, the temperature of the cooling mechanism, the first-order time derivative of the temperature of the stage, and the first or higher-order time derivative of the temperature of the cooling mechanism.

### BRIEF DESCRIPTION OF DRAWINGS

FIG. 1 is a diagram illustrating a configuration example of a plasma processing apparatus according to a first embodiment;

FIG. 2 is a plan view illustrating an example of a configuration of an electrostatic chuck according to the first embodiment;

FIG. 3 is a cross-sectional view illustrating the example of the configuration of the electrostatic chuck according to the first embodiment;

FIG. 4 is a block diagram illustrating a schematic configuration of a control unit according to the first embodiment;

FIG. 5 is a diagram illustrating an example of a thermal circuit representing a substrate and a main body portion according to the first embodiment;

FIG. 6 is a flowchart illustrating an example of a flow of substrate temperature control processing according to the first embodiment;

FIG. 7 is a block diagram illustrating a schematic configuration of an information processing apparatus according to a second embodiment; and

FIG. 8 is a flowchart illustrating an example of a flow of prediction processing according to the second embodiment.

### DESCRIPTION OF EMBODIMENTS

Hereinafter, embodiments of a plasma processing apparatus, a prediction method, a prediction program, and an information processing apparatus disclosed in the present application will be described in detail with reference to the drawings. Note that the plasma processing apparatus, the prediction method, the prediction program, and the information processing apparatus disclosed are not limited by the present embodiment.

A plasma processing apparatus that performs plasma processing on a substrate such as a semiconductor wafer (hereinafter, also referred to as “wafer”) is known. In the plasma processing apparatus, a technique for measuring an amount of heat input flowing from plasma to a substrate to grasp a state of plasma processing is expected.

### First Embodiment

### Apparatus Configuration

An example of a plasma processing apparatus according to the present disclosure will be described. In the embodiment described below, a case where the plasma processing apparatus according to the present disclosure is a plasma processing system having a system configuration of performing plasma processing will be described as an example.

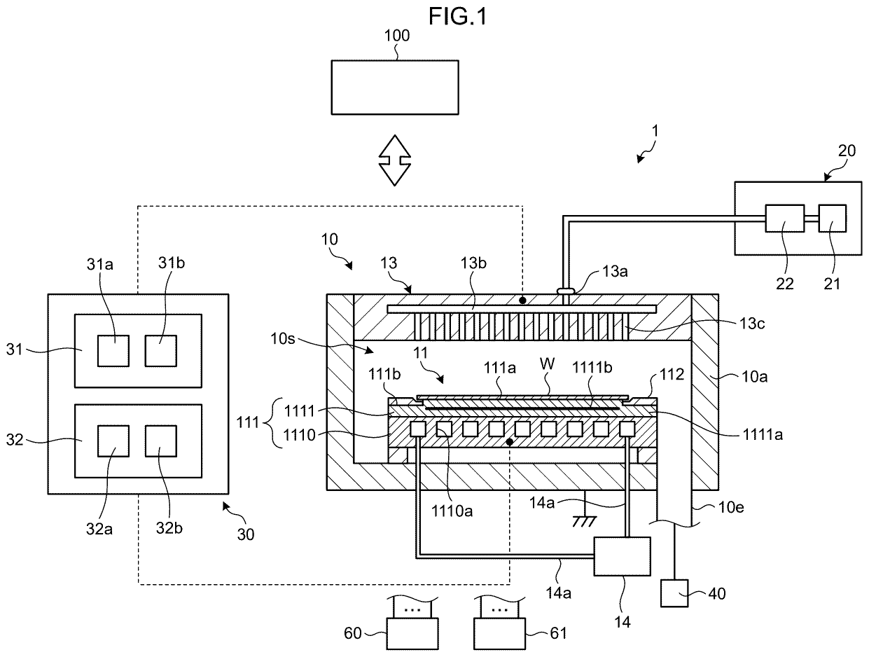

Hereinafter, a configuration example of the plasma processing system will be described. FIG. 1 is a diagram illustrating a configuration example of the plasma processing apparatus according to the first embodiment.

The plasma processing system includes a capacitively coupled plasma processing apparatus 1 and a control unit 100. The capacitively coupled plasma processing apparatus 1 includes a plasma processing chamber 10, a gas supply unit 20, a power supply 30, and an exhaust system 40. In addition, the plasma processing apparatus 1 includes a substrate support unit 11 and a gas introduction unit. The gas introduction unit is configured to introduce at least one type of process gas into the plasma processing chamber 10. The gas introduction unit includes a shower head 13. The substrate support unit 11 is disposed in the plasma processing chamber 10. The shower head 13 is disposed above the substrate support unit 11. In one embodiment, the shower head 13 forms at least a part of a ceiling of the plasma processing chamber 10. The plasma processing chamber 10 has a plasma processing space 10s defined by the shower head 13, a side wall 10a of the plasma processing chamber 10, and the substrate support unit 11. The plasma processing chamber 10 has at least one gas supply port for supplying at least one type of process gas to the plasma processing space 10s and at least one gas exhaust port for exhausting gas from the plasma processing space. The plasma processing chamber 10 is grounded. The shower head 13 and the substrate support unit 11 are electrically insulated from a case of the plasma processing chamber 10.

The substrate support unit 11 includes a main body portion 111 and a ring assembly 112. The main body portion 111 includes a central region 111a for supporting a substrate W and an annular region 111b for supporting the ring assembly 112. A wafer is an example of the substrate W. The annular region 111b of the main body portion 111 surrounds the central region 111a of the main body portion 111 in a plan view. The substrate W is disposed on the central region 111a of the main body portion 111, and the ring assembly 112 is disposed on the annular region 111b of the main body portion 111 so as to surround the substrate W on the central region 111a of the main body portion 111. Accordingly, the central region 111a is also called a substrate support surface for supporting the substrate W, and the annular region 111b is also called a ring support surface for supporting the ring assembly 112.

In one embodiment, the main body portion 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a includes the central region 111a. In one embodiment, the ceramic member 1111a also includes the annular region 111b. Another member, such as an annular electrostatic chuck or an annular insulating member, that surrounds the electrostatic chuck 1111 may include the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled with a radio frequency (RF) power supply 31 and/or a direct current (DC) power supply 32 described below may be disposed in the ceramic member 1111a. In this case, at least one RF/DC electrode functions as a lower electrode. When a bias RF signal and/or DC signal described below is supplied to at least one RF/DC electrode, the RF/DC electrode is also called a bias electrode. The conductive member of the base 1110 and at least one RF/DC electrode may function as a plurality of lower electrodes. In addition, the electrostatic electrode 1111b may also function as a lower electrode. Accordingly, the substrate support unit 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

In addition, the substrate support unit 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid such as brine or gas flows through the flow path 1110a. In one embodiment, the flow path 1110a is formed in the base 1110, and one or more heaters are disposed in the ceramic member 1111a of the electrostatic chuck 1111. The flow path 1110a is connected to pipes 14a at both ends, and is connected to a chiller unit 14 via the pipe 14a. The chiller unit 14 stores, for example, a coolant such as brine, and supplies the stored coolant to one of the pipes 14a. The coolant supplied from the chiller unit 14 is supplied to the flow path 1110a via one of the pipes 14a, flows from one end to the other end of the flow path 1110a, and returns to the chiller unit 14 via the other pipe 14a. The chiller unit 14 is configured such that a temperature of the stored coolant is changeable. In addition, the chiller unit 14 incorporates a temperature sensor such that the temperature of the supplied coolant can be measured. The chiller unit 14 changes the temperature of the stored coolant under the control of the control unit 100. In addition, the chiller unit 14 outputs the temperature of the coolant measured by the temperature sensor to the control unit 100. The plasma processing apparatus 1 is configured such that a temperature of the main body portion 111 is controllable by heating the main body portion 111 with a heater while circulating the coolant with the controlled temperature from the chiller unit 14 through the flow path 1110a for cooling. In the embodiment, the main body portion 111 corresponds to the stage according to the present disclosure. In addition, in the embodiment, the central region 111a corresponds to the placement surface according to the present disclosure. In addition, in the embodiment, the coolant, the flow path 1110a, and the like correspond to the cooling mechanism according to the present disclosure.

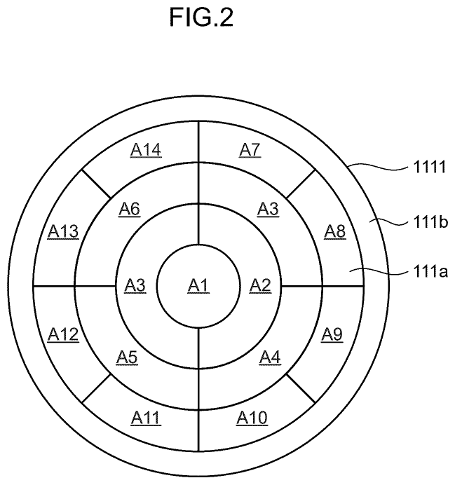

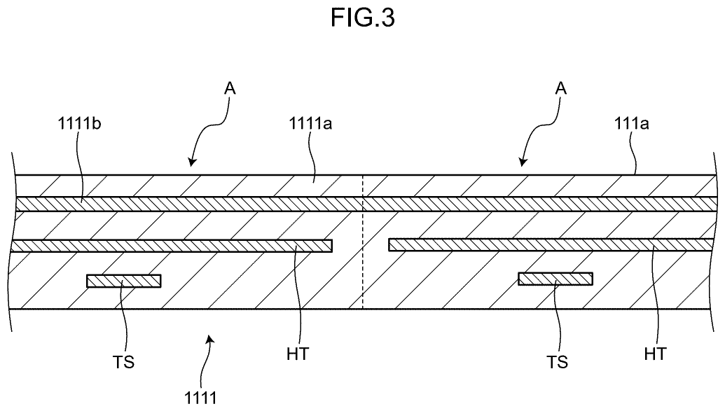

Here, a configuration of the electrostatic chuck 1111 of the substrate support unit 11 will be described. FIG. 2 is a plan view illustrating an example of the configuration of the electrostatic chuck 1111 according to the first embodiment. FIG. 3 is a cross-sectional view illustrating the example of the configuration of the electrostatic chuck 1111 according to the first embodiment.

FIG. 2 illustrates a plan view of an upper surface of the electrostatic chuck 1111. The upper surface of the electrostatic chuck 1111 is divided into the central region 111a and the annular region 111b. The central region 111a is a substantially circular region in a plan view. The substrate W is placed on an upper surface of the central region 111a. A diameter of the central region 111a is substantially the same as or slightly smaller than a diameter of the substrate W. The annular region 111b is a region surrounding the central region 111a, and extends in a substantially annular shape. In one embodiment, an upper surface of the annular region 111b is at a position lower than the upper surface of the central region 111a.

The central region 111a is divided into a plurality of areas A1 to A14. Hereinafter, when collectively referred to without distinguishing therebetween, the areas A1 to A14 will be referred to as the areas A. Each of the areas A is a region divided from the central region 111a and forms a part of the central region 111a. For example, as illustrated in FIG. 2, the center of the central region 111a is divided into a circular area A1. In addition, the central region 111a is divided into a plurality of annular regions concentric with the circular area A1, and the plurality of annular regions are respectively divided into a plurality of arc-shaped areas A2 to A14 in a circumferential direction. The arc-shaped areas A2 to A14 are divided such that an angular width becomes smaller toward the outer circumference. The flow path 1110a is formed in the base 1110 so as to pass through lower portions of all the areas A. A division method of the areas A illustrated in FIG. 2 is merely an example and is not limited thereto. For example, the central region 111a may be divided such that a width of the arc-shaped areas A in a radial direction becomes smaller toward the outer circumference. In addition, in the central region 111a, the regions concentric with the center may be respectively divided into the areas A at every fixed angle. In addition, the central region 111a may be divided into the areas A in a lattice pattern. In addition, in order to finely control a temperature distribution of the central region 111a, the central region 111a may be divided into a larger number of areas A. For example, the central region 111a may be divided into 100 or more areas A. In addition, the division method of the areas A illustrated in FIG. 2 illustrates a case where the annular region 111b is not divided, but the present disclosure is not limited thereto. The annular region 111b may also be divided into a plurality of areas A. For example, the annular region 111b may also be divided into a plurality of arc-shaped areas A in the circumferential direction.

In the electrostatic chuck 1111, a heater HT and a temperature sensor TS are provided for each of the areas A. FIG. 3 schematically illustrates a partial cross-section of two areas A of the electrostatic chuck 1111. The electrostatic electrode 1111b is disposed in the ceramic member 1111a. In addition, the heater HT and the temperature sensor TS are disposed in the ceramic member 1111a for each of the areas A. The heater HT generates heat when supplied with power, and heats the area A. In the embodiment, the heater HT corresponds to the heating mechanism according to the present disclosure. In addition, in the embodiment, the temperature sensor TS corresponds to the measurement unit according to the present disclosure.

Reference is made back to FIG. 1. Each of the heaters HT is connected to a heater power supply 60. Each of the temperature sensors TS is connected to a temperature detection unit 61. In FIG. 1, wirings for connecting each of the heaters HT to the heater power supply 60 and wirings for connecting each of the temperature sensors TS to the temperature detection unit 61 are partially omitted.

The heater power supply 60 supplies power to each of the heaters HT. The heater power supply 60 is configured to adjust power to be supplied to each of the heaters HT individually. For example, the heater power supply 60 performs pulse width modulation (PWM) control of the power to be supplied to each of the heaters HT. In the PWM control, power to be output is controlled by periodically switching between on and off during one period. The heater power supply 60 is configured to supply predetermined power to each of the heaters HT, and controls the power to be supplied to each of the heaters HT by changing a ratio of on duration (duty ratio) during one period. The heater power supply 60 adjusts the power to be supplied to each of the heaters HT based on control data input from the control unit 100. When the PWM control of the power to be supplied is performed, an amount of heat generated by each of the heaters HT can be controlled. Each of the heaters HT generates heat with the power supplied from the heater power supply 60, and heats the area A.

The temperature detection unit 61 measures a resistance value of each of the temperature sensors TS, and detects a temperature of the temperature sensor TS disposed in the area A based on the measured resistance value.

The temperature sensor TS may be formed of a material of which a resistance value changes depending on a temperature. The temperature sensor TS is, for example, a thermistor. In addition, the temperature sensor TS may be a thin film formed of any one of materials consisting of tungsten, nickel, molybdenum, copper, silver, platinum, and aluminum. The temperature detection unit 61 may measure a current and a voltage of the power to be supplied to each of the temperature sensors TS, obtain the resistance value of the temperature sensor TS from the measured current and voltage, and detect the temperature of the main body portion 111 of each of the areas A based on the obtained resistance value.

The shower head 13 is configured to introduce at least one type of process gas from the gas supply unit 20 into the plasma processing space 10s. The shower head 13 includes at least one gas supply port 13a, at least one gas diffusion chamber 13b, and a plurality of gas introduction ports 13c. The process gas supplied to the gas supply port 13a passes through the gas diffusion chamber 13b, and is introduced from the plurality of gas introduction ports 13c into the plasma processing space 10s. In addition, the shower head 13 includes at least one upper electrode. In addition to the shower head 13, the gas introduction unit may include one or more side gas injectors (SGI) attached to one or more openings formed on the side wall 10a.

The gas supply unit 20 may include at least one gas source 21 and at least one piece of flow control equipment 22. In one embodiment, the gas supply unit 20 is configured to supply at least one type of process gas from the corresponding gas source 21 to the shower head 13 through the corresponding flow control equipment 22. Each piece of the flow control equipment 22 may include, for example, a mass flow controller or pressure control type flow control equipment. Further, the gas supply unit 20 may include one or more flow modulation devices that modulate or pulse a flow volume of at least one type of process gas.

The power supply 30 includes the RF power supply 31 coupled to the plasma processing chamber 10 through at least one impedance matching circuit. The RF power supply 31 is configured to supply at least one RF signal (RF power) to at least one lower electrode and/or at least one upper electrode. As a result, plasma is formed from at least one type of process gas supplied to the plasma processing space 10s. Accordingly, the RF power supply 31 may function as at least a part of a plasma generation unit configured to generate plasma from one or more types of process gas in the plasma processing chamber 10. In addition, by supplying a bias RF signal to at least one lower electrode, a bias potential is generated in the substrate W, and ion components in the formed plasma can be drawn into the substrate W.

In one embodiment, the RF power supply 31 includes a first RF generation unit 31a and a second RF generation unit 31b. The first RF generation unit 31a is coupled to at least one lower electrode and/or at least one upper electrode through at least one impedance matching circuit, and is configured to generate a source RF signal (source RF power) for plasma generation. In one embodiment, the source RF signal has a frequency in a range of 10 MHz to 150 MHz. In one embodiment, the first RF generation unit 31a may be configured to generate a plurality of source RF signals having different frequencies. The one or more generated source RF signals are supplied to at least one lower electrode and/or at least one upper electrode.

The second RF generation unit 31b is coupled to at least one lower electrode through at least one impedance matching circuit, and is configured to generate the bias RF signal (bias RF power). A frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generation unit 31b may be configured to generate a plurality of bias RF signals having different frequencies. The one or more generated bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generation unit 32a and a second DC generation unit 32b. In one embodiment, the first DC generation unit 32a is connected to at least one lower electrode and is configured to generate a first DC signal. The generated first DC signal is applied to at least one lower electrode. In one embodiment, the second DC generation unit 32b is connected to at least one upper electrode and is configured to generate a second DC signal. The generated second DC signal is applied to at least one upper electrode.

In various embodiments, at least one of the first and second DC signals is pulsed. In this case, a sequence of voltage pulses is applied to at least one lower electrode and/or at least one upper electrode. The voltage pulses may have a pulse waveform of a rectangular, trapezoidal, or triangular shape, or a combination thereof. In one embodiment, a waveform generation unit for generating a sequence of voltage pulses from the DC signal is connected between the first DC generation unit 32a and at least one lower electrode. Accordingly, the first DC generation unit 32a and the waveform generation unit configure a voltage pulse generation unit. When the second DC generation unit 32b and the waveform generation unit configure the voltage pulse generation unit, the voltage pulse generation unit is connected to at least one upper electrode. The voltage pulses may have a positive polarity or a negative polarity. In addition, the sequence of voltage pulses may include one or more positive voltage pulses and one or more negative voltage pulses in one period. The first and second DC generation units 32a and 32b may also be provided in addition to the RF power supply 31, or the first DC generation unit 32a may be provided instead of the second RF generation unit 31b.

The exhaust system 40 may be connected to a gas exhaust port 10e provided, for example, in the bottom of the plasma processing chamber 10. The exhaust system 40 may include a pressure regulation valve and a vacuum pump. A pressure in the plasma processing space 10s is adjusted by the pressure regulation valve. The vacuum pump may include a turbomolecular pump, a dry pump, or a combination thereof.

An operation of the plasma processing apparatus 1 configured as described above is overall controlled by the control unit 100. The control unit 100 is, for example, a computer, and controls each of the units of the plasma processing apparatus 1. The control unit 100 controls the plasma processing apparatus 1 to perform various steps described in the present disclosure.

### Configuration of Control Unit

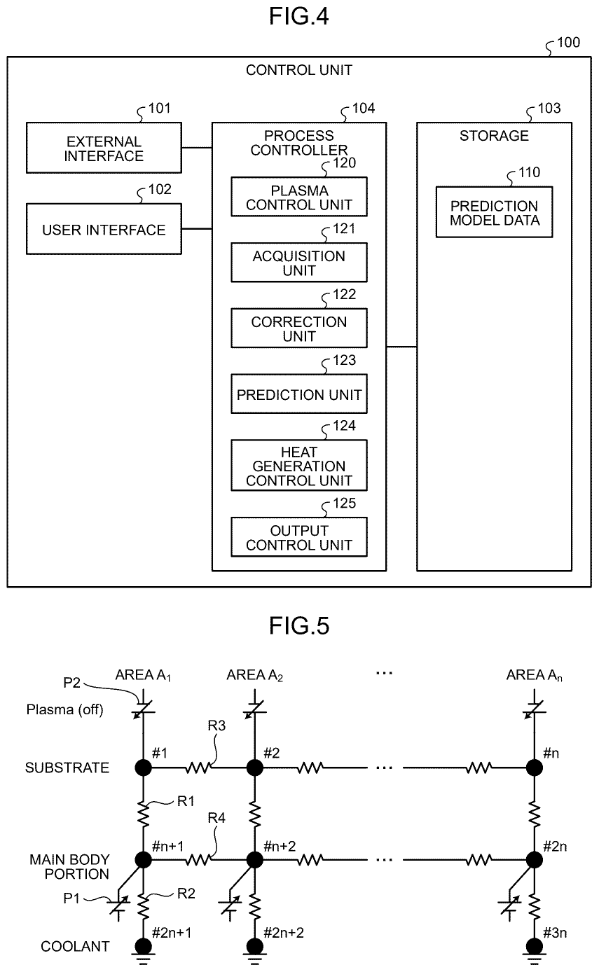

Next, the control unit 100 will be described. FIG. 4 is a block diagram illustrating a schematic configuration of the control unit 100 according to the first embodiment. The control unit 100 includes an external interface 101, a user interface 102, a storage 103, and a process controller 104.

The external interface 101 is configured to be communicable with each of the units of the plasma processing apparatus 1 to input and output various types of data. The user interface 102 is configured with a keyboard with which a process manager performs an input operation of a command for managing the plasma processing apparatus 1, a display that visualizes and displays an operating status of the plasma processing apparatus 1, and the like.

The storage 103 stores a control program (software) and various programs for implementing various processes to be performed by the plasma processing apparatus 1 under the control of the process controller 104. In addition, the storage 103 stores various types of data used for the programs to be executed by the process controller 104. For example, the storage 103 stores recipes where processing condition data and the like are stored and prediction model data 110. The programs and data may be used in a state of being stored in a computer-readable recording medium (for example, a hard disk, an optical disk such as a DVD, a flexible disk, or a semiconductor memory). In addition, the programs and data can also be used online by being transmitted as necessary from another apparatus through, for example, a dedicated line.

The prediction model data 110 is data storing a prediction model for predicting an amount of heat input from the plasma to the substrate W based on the amount of heat generated by the heater HT, the temperature of the main body portion 111, the temperature of the coolant, a first-order time derivative of the temperature of the main body portion 111, and a first or higher-order time derivative of the temperature of the coolant. In the present embodiment, the prediction model is a calculation formula for predicting the amount of heat input from the plasma to the substrate W in each of the areas A based on the amount of heat generated by the heater HT in each of the areas A, the temperature of the main body portion 111, the temperature of the coolant, the first-order time derivative of the temperature of the main body portion 111, and the first or higher-order time derivative of the temperature of the coolant. The details of the prediction model will be described below.

The process controller 104 includes a processor such as a central processing unit (CPU) or a micro processing unit (MPU), and controls each of the units of the plasma processing apparatus 1. The process controller 104 includes an internal memory for storing the programs and data, reads the control program stored in the storage 103, and executes the processing of the read control program. The process controller 104 functions as various processing units by the operation of the control program. For example, the process controller 104 has functions of a plasma control unit 120, an acquisition unit 121, a correction unit 122, a prediction unit 123, a heat generation control unit 124, and an output control unit 125. In the present embodiment, an example in which the process controller 104 has the functions of the plasma control unit 120, the acquisition unit 121, the correction unit 122, the prediction unit 123, the heat generation control unit 124, and the output control unit 125 will be described. However, the functions of the plasma control unit 120, the acquisition unit 121, the correction unit 122, the prediction unit 123, the heat generation control unit 124, and the output control unit 125 may be distributed and implemented by a plurality of controllers.

The plasma control unit 120 controls each of the units of the plasma processing apparatus 1, and controls plasma processing.

The acquisition unit 121 periodically acquires the amount of heat generated by each of the heaters HT, the temperature of the main body portion 111, and the temperature of the coolant. In the present embodiment, the acquisition unit 121 periodically acquires the temperature of the coolant, and the amount of heat generated by the heater HT and the temperature of the main body portion 111 in each of the areas A.

The details of the correction unit 122, the prediction unit 123, and the output control unit 125 will be described below.

The heat generation control unit 124 controls the heater power supply 60 through the external interface 101, and controls the amount of heat generated by each of the heaters HT. For example, the heat generation control unit 124 outputs control data designating supply power for each of the heaters HT to the heater power supply 60, and controls the amount of heat generated by each of the heaters HT. In the present embodiment, the heat generation control unit 124 outputs control data designating a duty ratio of each of the heaters HT to the heater power supply 60. The heater power supply 60 supplies power to each of the heaters HT at the designated duty ratio based on the control data. The heater HT generates heat with the amount of heat generated corresponding to the supplied power. For example, the heater power supply 60 is configured to supply a power of 100 W per unit time to one heater HT, and when the duty ratio is designated as 20%, controls the duty ratio of the power to be supplied to the heater HT to 20% to supply a power of 20 W per unit time to the heater HT. In this case, the heater HT generates heat with an amount of heat generated of 20 W per unit time.

Next, the flow of plasma processing will be simply described.

The substrate W is loaded into the plasma processing chamber 10 through loading and unloading ports (not illustrated) by a transfer mechanism such as a transfer arm, and is placed on the central region 111a of the substrate support unit 11.

The heat generation control unit 124 controls the amount of heat generated by the heater HT. A preset temperature is set in the heat generation control unit 124. The temperature detection unit 61 detects the temperature of the main body portion 111 in each of the areas A using each of the temperature sensors TS. The heat generation control unit 124 controls the amount of heat generated by the heater HT such that the temperature of the main body portion 111 in each of the areas A detected by the temperature detection unit 61 is the preset temperature. For example, during the plasma processing, in the heat generation control unit 124, the preset temperature of the substrate W stored in the recipes is set for each of the areas A of the substrate W. The heat generation control unit 124 controls the amount of heat generated by the heater HT such that the temperature of the main body portion 111 in each of the areas A is the preset temperature.

The plasma control unit 120 controls the plasma processing. For example, the plasma control unit 120 controls the exhaust system 40 to evacuate the inside of the plasma processing chamber 10 to a predetermined degree of vacuum. The plasma control unit 120 controls the gas supply unit 20 to introduce the process gas from the gas supply unit 20 into the plasma processing space 10s. In conjunction with the introduction of the process gas, the plasma control unit 120 controls the power supply 30 to supply the source RF signal and the bias RF signal from the first RF generation unit 31a and the second RF generation unit 31b and to generate plasma in the plasma processing chamber 10.

Meanwhile, in the plasma processing apparatus 1, it is desired to measure the amount of heat input flowing from the plasma to the substrate W. The amount of heat input flowing from the plasma to the substrate W varies depending on a state of the plasma. Accordingly, in the plasma processing apparatus 1, when the amount of heat input flowing from the plasma to the substrate W is measured, the state of the plasma can be grasped. For example, the amount of heat input from the plasma to the substrate W in each of the areas A varies depending on a density distribution of the plasma. Accordingly, in the plasma processing apparatus 1, when the amount of heat input flowing from the plasma to the substrate W in each of the areas A is measured, the density distribution of the plasma can be grasped.

Accordingly, the plasma processing apparatus 1 according to the present embodiment predicts the amount of heat input from the plasma to the substrate W as follows.

The acquisition unit 121 periodically acquires the amount of heat generated by each of the heaters HT, the temperature of the main body portion 111, and the temperature of the coolant. In the present embodiment, the acquisition unit 121 periodically acquires the temperature of the coolant, and the amount of heat generated by the heater HT and the temperature of the main body portion 111 in each of the areas A.

For example, the acquisition unit 121 acquires, as the temperature of the main body portion 111 in each of the areas A, the temperature of the temperature sensor TS disposed in each of the areas A from the temperature detection unit 61 via the external interface 101. In addition, the acquisition unit 121 acquires the temperature of the coolant from the chiller unit 14 via the external interface 101. A thermometer may be added to the pipe 14a to acquire the temperature of the coolant flowing to the flow path 1110a, or the temperature of the coolant flowing out from the flow path 1110a may be separately acquired.

In addition, the acquisition unit 121 acquires the amount of heat generated by the heater HT in each of the areas A from the heat generation control unit 124. For example, the acquisition unit 121 acquires, from the heat generation control unit 124, a supply power to the heater HT in each of the areas A that is controlled by the heat generation control unit 124. The acquisition unit 121 specifies the acquired supply power to the heater HT in each of the areas A as the amount of heat generated by the heater HT in each of the areas A. In the present embodiment, the acquisition unit 121 acquires, from the heat generation control unit 124, the duty ratio of the heater HT in each of the areas A that is controlled by the heat generation control unit 124. The acquisition unit 121 obtains the supply power to the heater HT in each of the areas A based on the duty ratio of the heater HT in each of the areas A and the power that can be supplied from the heater power supply 60 to the heater HT in each of the areas A. For example, when the duty ratio is 20% and the heater power supply 60 can supply a power of 100 W per unit time to the heater HT of the area A, the acquisition unit 121 specifies the supply power to the heater HT as 20 W per unit time. The acquisition unit 121 specifies 20 W per unit time as the amount of heat generated by the heater HT.

The correction unit 122 corrects the temperature of the coolant acquired by the acquisition unit 121, to the temperature of the coolant in each of the areas A along the flow path 1110a.

The prediction unit 123 predicts the amount of heat input from the plasma to the substrate W in each of the areas A using the prediction model for predicting the amount of heat input from the plasma to the substrate W.

Here, the prediction model will be described. The prediction model may be expressed as a mathematical model for calculating the amount of heat input flowing from the plasma to the substrate W in each of the areas A. The prediction model calculates the amount of heat input from the plasma in each of the areas A by multiplying the amount of heat generated by the heater HT, the temperature of the main body portion 111, the temperature of the coolant, the first-order time derivative of the temperature of the main body portion 111, and the first or higher-order time derivative of the temperature of the coolant by coefficients, respectively, and adding the obtained values. For example, the prediction model calculates the amount of heat input flowing from the plasma to the substrate W in each of the areas A by multiplying the above factors for the area A and all of the other areas A by the coefficients, respectively, and adding the obtained values. For example, the prediction model may be expressed as a calculation formula such as the following Expression (1), based on a thermal network method or a polynomial approximation model.

$$[ \begin{matrix}{P}_{1} \\ ⋮ \\ {P}_{n}\end{matrix} ] = [ \begin{matrix}{a}_{1 , 1} & ⋯ & {a}_{1 , n} \\ ⋮ & ⋱ & ⋮ \\ {a}_{n , 1} & ⋯ & {a}_{n , n}\end{matrix} ] [ \begin{matrix}{T}_{1} \\ ⋮ \\ {T}_{n}\end{matrix} ] + [ \begin{matrix}{b}_{1 , 1} & ⋯ & {b}_{1 , n} \\ ⋮ & ⋱ & ⋮ \\ {b}_{n , 1} & ⋯ & {b}_{n , n}\end{matrix} ] \text{} [ \begin{matrix}{p}_{1} \\ ⋮ \\ {p}_{n}\end{matrix} ] + [ \begin{matrix}{c}_{1 , 1} & ⋯ & {c}_{1 , n} \\ ⋮ & ⋱ & ⋮ \\ {c}_{n , 1} & ⋯ & {c}_{n , n}\end{matrix} ] [ \begin{matrix}\frac{d}{dt} {T}_{1} \\ ⋮ \\ \frac{d}{dt} {T}_{n}\end{matrix} ] + [ \begin{matrix}{d}_{1 , 1} & ⋯ & {d}_{1 , n} \\ ⋮ & ⋱ & ⋮ \\ {d}_{n , 1} & ⋯ & {d}_{n , n}\end{matrix} ] [ \begin{matrix}{T}_{1}^{′} \\ ⋮ \\ {T}_{n}^{′}\end{matrix} ] + [ \begin{matrix}{e}_{1 , 1} & ⋯ & {e}_{1 , n} \\ ⋮ & ⋱ & ⋮ \\ {e}_{n , 1} & ⋯ & {e}_{n , n}\end{matrix} ] [ \begin{matrix}\frac{d}{dt} {T}_{1}^{′} \\ ⋮ \\ \frac{d}{dt} {T}_{n}^{′}\end{matrix} ] + [ \begin{matrix}{f}_{1 , 1} & ⋯ & {f}_{1 , n} \\ ⋮ & ⋱ & ⋮ \\ {f}_{n , 1} & ⋯ & {f}_{n , n}\end{matrix} ] [ \begin{matrix}\frac{{d}^{2}}{{dt}^{2}} {T}_{1}^{′} \\ ⋮ \\ \frac{{d}^{2}}{{dt}^{2}} {T}_{n}^{′}\end{matrix} ] \qquad ( 1 )$$

Here, n denotes a number sequentially assigned to each of the areas A.
P₁ to Pₙ denote amounts of heat input flowing from the plasma to the substrate W in the areas A assigned with numbers 1 to n, respectively.
T₁ to Tₙ denote temperatures of the main body portion 111 in the areas A assigned with numbers 1 to n, respectively.
p₁ to pₙ denote amounts of heat generated by the heaters HT in the areas A assigned with numbers 1 to n, respectively.
T′₁ to T′ₙ denote temperatures of the coolant in the areas A assigned with numbers 1 to n, respectively.
a_{1,1} to a_{n,n} denote coefficients for the temperatures T₁ to Tₙ of the main body portion 111, respectively.
b_{1,1} to b_{n,n} denote coefficients for the amounts of heat p₁ to pₙ generated by the heaters HT, respectively.
c_{1,1} to c_{n,n} denote coefficients for first-order time derivatives of the temperatures T₁ to Tₙ of the main body portion 111, respectively.
d_{1,1} to d_{n,n} denote coefficients for the temperatures T′₁ to T′ₙ of the coolant, respectively.
e_{1,1} to e_{n,n} denote coefficients for first-order time derivatives of the temperatures T′₁ to T′ₙ of the coolant, respectively.
f_{1,1} to f_{n,n} denote coefficients for second-order time derivatives of the temperatures T′₁ to T′ₙ of the coolant, respectively.

The flow of heat in portions relating to the substrate W and the main body portion 111 can be expressed as a thermal circuit by the thermal network method. FIG. 5 is a diagram illustrating an example of a thermal circuit representing the substrate W and the main body portion 111 according to the first embodiment.

In the thermal circuit illustrated in FIG. 5, portions of the substrate W in the areas A assigned with numbers 1 to n are represented as nodes #1 to #n, portions of the main body portion 111 in the areas A assigned with numbers 1 to n are represented as nodes #n+1 to #2n, and portions of the coolant in the flow path 1110a are represented as nodes #2n+1 to #3n. The coolant flows in the flow path 1110a. Heat transferred to the coolant flows along with the coolant. Therefore, the nodes #2n+1 to #3n are illustrated as constant potential points using ground symbols.

The plasma processing apparatus 1 transfers heat according to a temperature difference between the substrate W and the main body portion 111 and a temperature difference between the main body portion 111 and the coolant in the flow path 1110a for each of the areas A. In the thermal circuit illustrated in FIG. 5, a thermal resistance between the substrate W and the main body portion 111 is represented as a thermal resistance R1, and a thermal resistance between the main body portion 111 and the coolant in the flow path 1110a is represented as a thermal resistance R2.

In addition, the plasma processing apparatus 1 transfers heat between the areas A according to the temperature difference for the substrate W and the main body portion 111. In the thermal circuit illustrated in FIG. 5, a thermal resistance between the areas A of the substrate W is represented as a thermal resistance R3, and a thermal resistance between the areas A of the main body portion 111 is represented as a thermal resistance R4.

In addition, in the plasma processing apparatus 1, for each of the areas A, the heater HT is provided in the main body portion 111, and the amount of heat generated by the heater HT is transferred to the main body portion 111. In the thermal circuit illustrated in FIG. 5, a variable heat source P1 representing the heater HT is connected to each of the nodes #n+1 to #2n representing the main body portion 111.

In addition, in the plasma processing apparatus 1, heat is input from the plasma to the substrate W for each of the areas A. In the thermal circuit illustrated in FIG. 5, the plasma in each of the areas A assigned with numbers 1 to n is represented as a variable heat source P2. In the thermal circuit illustrated in FIG. 5, the variable heat source P2 representing the plasma is connected to each of the nodes #1 to #n representing the substrate W.

Regarding the nodes #1 to #3n, simultaneous heat balance equations can be expressed as the following Expressions (2-1) to (2-3n).

$$\{ \begin{matrix}{Q}_{1} + \sum {G}_{1 , i} ( {T}_{i} - {T}_{1} ) = {C}_{1} \frac{{dT}_{1}}{dt} & ⋯ & ( 2 - 1 ) \\ {Q}_{2} + \sum {G}_{2 , i} ( {T}_{i} - {T}_{2} ) = {C}_{2} \frac{{dT}_{2}}{dt} & ⋯ & ( 2 - 2 ) \\ ⋮ & ⋮ & \\ {Q}_{3 n} + \sum {G}_{3 n , i} ( {T}_{i} - {T}_{3 n} ) = {C}_{3 n} \frac{{dT}_{3 n}}{dt} & ⋯ & ( 2 - 3 n )\end{matrix}$$

Here,
Q denotes an amount of heat input (W) to each of the nodes. For example, Q₁ denotes an amount of heat input to the node #1.
G denotes a thermal conductivity (W/K) between the respective nodes. For example, G_{1,i} denotes a thermal conductivity between the node #1 and the node #i.
T denotes a temperature (degC) of each of the nodes. For example, T₁ denotes a temperature of the node #1.
t denotes time (sec).
C denotes a heat capacity of each of the nodes. For example, C₁ denotes a heat capacity of the node #1.

On the left side of each of the simultaneous heat balance equations, for each of the nodes, each of the temperature differences from the nodes #1 to #3n (i denotes 1 to 3n) is multiplied by the thermal conductivity G to obtain a summation of products, and the amount of heat input Q and the summation are added. For example, on the left side of Expression (2-1), for the node #1, each of the temperature differences (Tᵢ-T₁) from the nodes #1 to #3n (i denotes 1 to 3n) is multiplied by the thermal conductivity G_{1,i} to obtain the summation of the products, and the amount of heat input Q₁ and the summation are added.

Expressions (2-1) to (2-3n) are expressed as expressions including terms of heat transfer between all the nodes #1 to #3n. For nodes between which heat transfer is not considered, the thermal conductivity G between the nodes is, for example, zero. For example, for nodes that are not connected in the thermal circuit illustrated in FIG. 5, the thermal conductivity G between the nodes is, for example, zero.

For example, the simultaneous heat balance equations for the node #1 illustrated in FIG. 5 can be expressed as the following Expression (3).

$${Q}_{1} = {C}_{1} \frac{{dT}_{1}}{dt} - {G}_{1 , 2} ( {T}_{2} - {T}_{1} ) - … - {G}_{1 , n} ( {T}_{n} - {T}_{1} ) - {G}_{1 , n + 1} ( {T}_{n + 1} - {T}_{1} ) \qquad ( 3 )$$

Expression (1) can be obtained from the simultaneous heat balance equations for the nodes #1 to #3n. In addition, even when the polynomial approximation model is used, Expression (1) can be similarly obtained.

A value of each of the coefficients a_{1,1} to a_{n,n}, b_{1,1} to b_{n,n}, c_{1,1} to c_{n,n}, d_{1,1} to d_{n,n}, e_{1,1} to e_{n,n}, and f_{1,1} to f_{n,n} of Expression (1) can be determined by performing fitting using fitting data. The fitting data is generated, for example, by measuring the amount of heat input flowing from the plasma to the substrate W in each of the areas A, the amount of heat generated by the heater HT, the temperature of the main body portion 111, and the temperature of the coolant using the plasma processing apparatus 1. The fitting data is generated based on the amount of heat input from the plasma in each of the areas A, the amount of heat generated by the heater HT, the temperature of the main body portion 111, the temperature of the coolant, the first-order time derivative of the temperature of the main body portion 111, the first-order time derivative of the temperature of the coolant, and the second-order time derivative of the temperature of the coolant.

The amount of heat input flowing from the plasma to the substrate W in each of the areas A is calculated from the simultaneous heat balance equations for the substrate W in each of the areas A. For example, for the nodes #1 to #3n, in the simultaneous heat balance equations represented by the following Expressions (2-1) to (2-3n), the thermal conductivity G can be calculated from the temperatures of the nodes #1 to #3n, temporal changes in the temperatures, and the amount of heat generated by the heater HT. The amount of heat input flowing from the plasma to the substrate W in each of the areas A is calculated using the simultaneous heat balance equations for the nodes #1 to #n.

When the fitting data is generated, the substrate W is placed on the central region 111a of the substrate support unit 11. When the fitting data is generated, the process controller 104 controls the heater power supply 60 to generate heat from each of the heaters HT while circulating the coolant from the chiller unit 14 through the flow path 1110a for cooling, in a state where plasma is generated. The process controller 104 measures the temperature of the substrate W in each of the areas A, the amount of heat generated by the heater HT, the temperature of the main body portion 111, and the temperature of the coolant. The temperature of the substrate W in each of the areas A is measured, for example, by disposing a temperature sensor such as an infrared camera in the plasma processing chamber 10. In addition, the temperature of the substrate W in each of the areas A is measured, for example, using a sensor substrate configured to measure the temperature. The process controller 104 periodically measures the temperature of the substrate W in each of the areas A, the amount of heat generated by the heater HT, the temperature of the main body portion 111, and the temperature of the coolant. The process controller 104 periodically performs measurement for a plurality of patterns obtained by varying conditions for generating plasma, the temperature of the coolant, and the amount of heat generated by each of the heaters HT, including a transition period in which the temperature changes. The process controller 104 calculates the amount of heat input flowing from the plasma to the substrate W in each of the areas A, based on the temperature of the substrate W in each of the areas A. When the fitting data is generated, the amount of heat input flowing from the plasma to the substrate W in each of the areas A may be measured using a sensor substrate or the like configured to measure the amount of heat input from the plasma. The process controller 104 generates fitting data storing the amount of heat input flowing from the plasma to the substrate W in each of the areas A, the amount of heat generated by the heater HT, the temperature of the main body portion 111, and the temperature of the coolant in association with the measured time.

The temperature of the coolant in each of the areas A may be the temperature of the coolant measured by the chiller unit 14, or may be the temperature of the coolant measured by the thermometer provided in the pipe 14a.

Here, the temperature of the coolant flowing through the flow path 1110a gradually increases due to heat input from the base 1110. Accordingly, the temperature of the coolant in each of the areas A in the fitting data may be corrected in response to temperature increase along the flow path 1110a. For example, the amount of increase in the temperature of the coolant when the coolant passes through the flow path 1110a is obtained. In addition, a total length of the flow path 1110a from one end where the coolant flows in to the other end of the flow path 1110a where the coolant flows out is obtained. In addition, a length of the flow path 1110a to each of the areas A is obtained. The length of the flow path 1110a to each of the areas A is measured from one end along the flow path 1110a. The total length of the flow path 1110a and the length of the flow path 1110a to each of the areas A may be obtained from design data of the base 1110, or may be obtained by actually measuring the base 1110. In correction of the temperature of the coolant, for each of the areas A, the amount of increase in the temperature of the coolant at the total length of the flow path 1110a is multiplied by a ratio of the length of the flow path 1110a to the area A with respect to the total length of the flow path 1110a, to calculate the amount of increase in the temperature of the coolant for each of the areas A. In correction of the temperature of the coolant, the temperature of the coolant for each of the areas A is calculated by adding the calculated amount of increase in the temperature of the coolant for each of the areas A to the temperature of the coolant measured by the chiller unit 14 or the thermometer provided in the pipe 14a. The amount of increase in the temperature of the coolant for each of the areas A may be obtained by simulation or the like.

An appropriate value of each of the coefficients a_{1,1} to a_{n,n}, b_{1,1} to b_{n,n}, c_{1,1} to c_{n,n}, d_{1,1} to d_{n,n}, e_{1,1} to e_{n,n}, and f_{1,1} to f_{n,n} can be specified by performing fitting of Expression (1) using the fitting data.

The prediction model data 110 stores Expression (1) where the specified values are set for the coefficients a_{1,1} to a_{n,n}, b_{1,1} to b_{n,n}, c_{1,1} to c_{n,n}, d_{1,1} to d_{n,n}, e_{1,1} to e_{n,n}, and f_{1,1} to f_{n,n}, respectively.

The acquisition unit 121 periodically acquires the amount of heat generated by each of the heaters HT, the temperature of the main body portion 111, and the temperature of the coolant. In the present embodiment, the acquisition unit 121 periodically acquires the temperature of the coolant, and the amount of heat generated by the heater HT and the temperature of the main body portion 111 in each of the areas A. A period in which the acquisition unit 121 acquires the temperature of the coolant, the amount of heat generated by the heater HT, and the temperature of the main body portion 111 may be a period in which a time derivative of the temperature of the main body portion 111 and a time derivative of the temperature of the coolant can be obtained. For example, the period is preferably 0.01 to 0.1 seconds and more preferably 0.0001 to 0.01 seconds.

The correction unit 122 corrects the temperature of the coolant acquired by the acquisition unit 121, to the temperature of the coolant in each of the areas A in response to temperature increase along the flow path 1110a. For example, for each of the areas A, the correction unit 122 multiplies the amount of increase in the temperature of the coolant at the total length of the flow path 1110a by the ratio of the length of the flow path 1110a up to the area A with respect to the total length of the flow path 1110a, to calculate the amount of increase in the temperature of the coolant for each of the areas A. The correction unit 122 calculates the temperature of the coolant for each of the areas A by adding the calculated amount of increase in the temperature of the coolant for each of the areas A to the temperature of the coolant measured by the chiller unit 14 or the thermometer provided in the pipe 14a. The correction unit 122 may calculate the temperature of the coolant for each of the areas A by adding the amount of increase in the temperature of the coolant for each of the areas A, which is obtained by simulation or the like, to the temperature of the coolant measured by the chiller unit 14 or the thermometer provided in the pipe 14a.

The prediction unit 123 predicts the amount of heat input from the plasma to the substrate W for each of the areas A using the prediction model stored in the prediction model data 110. The prediction unit 123 predicts the amount of heat input from the plasma to the substrate W for each of the areas A based on the corrected temperature of the coolant in each of the areas A, the acquired amount of heat generated by the heater HT in each of the areas A, and the temperature of the main body portion 111. For example, the prediction unit 123 predicts the amount of heat input in each of the areas A using Expression (1) based on the temperature of the coolant in each of the areas A, the amount of heat generated by the heater HT, the temperature of the main body portion 111, the first-order time derivative of the temperature of the main body portion 111, the first-order time derivative of the temperature of the coolant, and the second-order time derivative of the temperature of the coolant. For example, the prediction unit 123 substitutes the temperature of the coolant in each of the areas A, the amount of heat generated by the heater HT, the temperature of the main body portion 111, the first-order time derivative of the temperature of the main body portion 111, the first-order time derivative of the temperature of the coolant, and the second-order time derivative of the temperature of the coolant into Expression (1). The prediction unit 123 computes Expression (1) to calculate the amount of heat input from the plasma to the substrate W in each of the areas A. The prediction unit 123 can accurately predict the amount of heat input from the plasma to the substrate W using Expression (1).

The output control unit 125 performs various controls to output the amount of heat input from the plasma to the substrate W in each of the areas A, which is predicted by the prediction unit 123. For example, the output control unit 125 controls the user interface 102 to output information based on the amount of heat input from the plasma to the substrate W in each of the areas A, which is predicted by the prediction unit 123. For example, the output control unit 125 controls the user interface 102 to display an image representing a distribution of the amount of heat input in each of the areas A on the substrate W. In addition, for example, the output control unit 125 outputs data regarding the amount of heat input from the plasma to the substrate W in each of the areas A, which is predicted by the prediction unit 123, to an external terminal device via a network (not illustrated). In addition, for example, the output control unit 125 controls the storage 103 to store the data regarding the amount of heat input from the plasma to the substrate W in each of the areas A, which is predicted by the prediction unit 123.

### Specific Example of Flow of Prediction Processing

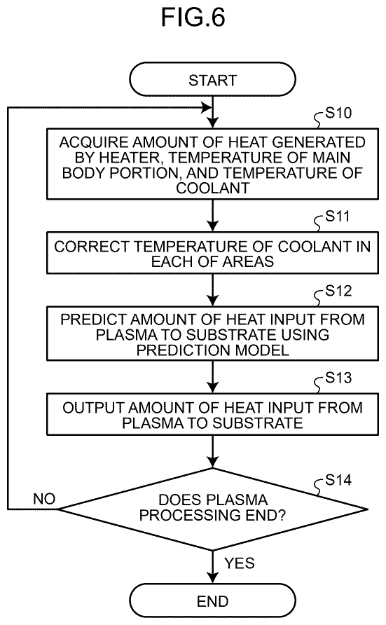

Next, a specific example of a flow of prediction processing in a prediction method according to the first embodiment will be described. FIG. 6 is a flowchart illustrating an example of the flow of the prediction processing according to the first embodiment. The prediction processing according to the first embodiment is performed when the plasma processing starts. When the plasma processing starts, in the heat generation control unit 124, the preset temperature of the substrate W stored in the recipes is set for each of the areas A of the substrate W.

The acquisition unit 121 acquires the amount of heat generated by the heater HT, the temperature of the main body portion 111, and the temperature of the coolant (Step S10). For example, the acquisition unit 121 acquires the temperature of the coolant, and the amount of heat generated by the heater HT and the temperature of the main body portion 111 in each of the areas A.

The correction unit 122 corrects the temperature of the coolant acquired by the acquisition unit 121, to the temperature of the coolant in each of the areas A (Step S11).

The prediction unit 123 predicts the amount of heat input from the plasma to the substrate W for each of the areas A using the prediction model stored in the prediction model data 110 (Step S12). For example, the prediction unit 123 predicts the amount of heat input in each of the areas A using Expression (1) based on the temperature of the coolant in each of the areas A, the amount of heat generated by the heater HT, the temperature of the main body portion 111, the first-order time derivative of the temperature of the main body portion 111, the first-order time derivative of the temperature of the coolant, and the second-order time derivative of the temperature of the coolant.

As a result, the plasma processing apparatus 1 according to the first embodiment can measure the amount of heat input flowing from the plasma to each of the areas A of the substrate W.

The output control unit 125 performs various controls to output the amount of heat input from the plasma to the substrate W in each of the areas A, which is predicted by the prediction unit 123 (Step S13). For example, the output control unit 125 controls the user interface 102 to display an image representing a distribution of the amount of heat input in each of the areas A on the substrate W.

As a result, a process manager can grasp the state of the plasma processing by checking the image displayed on the user interface 102. For example, the process manager can grasp the density distribution of the plasma from the image representing the distribution of the amount of heat input in each of the areas A.

The prediction unit 123 determines whether the plasma processing ends (Step S14). When the plasma processing does not end (Step S14: No), the process proceeds to Step S10 described above. When the plasma processing ends (Step S14: Yes), the process ends.

In the above-described embodiment, a case where the prediction model for each of the areas A includes the terms of heat transfer from the area A and all of the other areas A has been described as the example. However, the present disclosure is not limited to the example. For example, the prediction model for each of the areas A may include the terms of heat transfer from the corresponding area A and some of the other areas A. Some of the other areas A may be any areas A where heat transfer to the corresponding area A occurs, such as areas A surrounding the corresponding area A or areas A adjacent to the corresponding area A.

In addition, in the above-described embodiment, a case where the amount of heat input from the plasma to the substrate W is predicted for each of the areas A divided from the central region 111a of the main body portion 111 has been described as the example. However, the present disclosure is not limited to the example. For example, the amount of heat input from the plasma to the substrate W may be predicted by considering the central region 111a as one area A, without dividing the central region 111a of the main body portion 111 into the areas A.

In addition, in the above-described embodiment, the thermal circuit having the configuration of FIG. 5 is illustrated as the thermal circuit representing the substrate W and the main body portion 111. However, the present disclosure is not limited to the example. In the thermal circuit representing the substrate W and the main body portion 111, nodes may be added in consideration of heat transfer between the temperature sensor TS in the main body portion 111 and the heater HT. For example, the thermal circuit representing the substrate W and the main body portion 111 may have a circuit configuration in which nodes are added between the nodes #1 to #n and the nodes #n+1 to #2n of the thermal circuit having the configuration of FIG. 5, and the variable heat source P1 representing the heater HT is connected to each of the added nodes.

In addition, in the above-described embodiment, a case where the prediction model (for example, Expression (1)) obtained from the fitting data generated by the plasma processing apparatus 1 is stored in the prediction model data 110 has been described as the example. However, the present disclosure is not limited to the example. The prediction model data 110 may store a prediction model obtained from another plasma processing apparatus. For example, when a plurality of plasma processing apparatuses are operated, Expression (1) may be obtained by any one of the plasma processing apparatuses, and the obtained Expression (1) may be used for the plurality of plasma processing apparatuses. In addition, the prediction model of the prediction model data 110 may be provided by a manufacturer of the plasma processing apparatus. The prediction model may be able to adjust individual differences among the plasma processing apparatuses. For example, a correction term may be added to Expression (1) to absorb the individual differences among the plasma processing apparatuses. Each of the plasma processing apparatuses 1 may use a prediction model in which a correction term is adjusted according to the individual differences among the plasma processing apparatuses 1. For example, Expression (1) as a reference is obtained using a plasma processing apparatus as a reference. Each of the plasma processing apparatuses 1 stores Expression (1) in which the correction term is adjusted as the prediction model in the prediction model data 110.

In addition, in the above-described embodiment, a case where the plasma processing is performed on the semiconductor wafer as the substrate W has been described as the example, but the present disclosure is not limited thereto. The substrate W may be any one.

In addition, in the above-described embodiment, a case where the plasma processing apparatus is the plasma processing system that performs plasma etching processing has been described as the example. However, the present disclosure is not limited to the example. For example, the plasma processing apparatus may be a film forming apparatus that generates plasma to form a film, or may be a heat treatment apparatus that generates plasma to perform a heat treatment such as ashing.

In addition, in the above-described embodiment, a case where the information based on the predicted amount of heat input from the plasma to the substrate W is displayed on the user interface 102 has been described as the example. However, the present disclosure is not limited to the example. For example, the plasma processing apparatus may control the plasma processing based on the amount of heat input from the plasma to the substrate W. For example, the plasma processing apparatus may obtain the density distribution of the plasma based on the amount of heat input from the plasma to the substrate W in each of the areas A to control the plasma processing such that the predetermined density distribution is obtained.

As described above, the plasma processing system (the plasma processing apparatus) according to the first embodiment includes the main body portion 111 (the stage), the plasma processing chamber 10 (the chamber), the cooling mechanism (the coolant, the flow path 1110a, or the like), the heater HT (the heating mechanism), the temperature sensor TS (the measurement unit), the acquisition unit 121, and the prediction unit 123. The substrate W is placed on the main body portion 111. In the plasma processing chamber 10, the main body portion 111 is provided, and plasma is generated to perform plasma processing on the substrate W placed on the main body portion 111. The cooling mechanism is provided in the main body portion 111, and cools the main body portion 111. The heater HT is provided between the placement surface of the main body portion 111 on which the substrate W is placed and the cooling mechanism, and is configured to control the amount of heat generated and to heat the main body portion 111. The temperature sensor TS measures the temperature of the main body portion 111. The acquisition unit 121 periodically acquires the amount of heat generated by the heater HT, the temperature of the main body portion 111, and the temperature of the cooling mechanism. The prediction unit 123 predicts the amount of heat input flowing from the plasma to the substrate W using the calculation formula (for example, Expression (1)) based on the amount of heat generated by the heater HT, the temperature of the main body portion 111, and the temperature of the cooling mechanism that are acquired by the acquisition unit 121, the first-order time derivative of the temperature of the main body portion 111, and the first or higher-order time derivative of the temperature of the cooling mechanism, in which the calculation formula predicts the amount of heat input flowing from the plasma to the substrate W based on the amount of heat generated by the heater HT, the temperature of the main body portion 111, the temperature of the cooling mechanism, the first-order time derivative of the temperature of the main body portion 111, and the first or higher-order time derivative of the temperature of the cooling mechanism. As a result, the plasma processing system according to the first embodiment can measure the amount of heat input flowing from the plasma to the substrate W.

In addition, the calculation formula is a prediction model for predicting the amount of heat input flowing from the plasma to the substrate W based on the amount of heat generated by the heater HT, the temperature of the main body portion 111, the temperature of the cooling mechanism, the first-order time derivative of the temperature of the main body portion 111, and the first or higher-order time derivative of the temperature of the cooling mechanism. As a result, the plasma processing system according to the first embodiment can measure the amount of heat input flowing from the plasma to the substrate W using the prediction model.

In addition, the calculation formula is a mathematical model for calculating the amount of heat input flowing from the plasma to the substrate W by multiplying the amount of heat generated by the heater HT, the temperature of the main body portion 111, the temperature of the cooling mechanism, the first-order time derivative of the temperature of the main body portion 111, the first-order time derivative of the temperature of the cooling mechanism, and the second-order time derivative of the temperature of the cooling mechanism by coefficients, respectively, and adding the obtained values. A value of each of the coefficients of the mathematical model is determined using predetermined data representing a relationship between the amount of heat input flowing from the plasma to the substrate W, the amount of heat generated by the heater HT, the temperature of the main body portion 111, the temperature of the cooling mechanism, the first-order time derivative of the temperature of the main body portion 111, the first-order time derivative of the temperature of the cooling mechanism, and the second-order time derivative of the temperature of the cooling mechanism. As a result, the plasma processing system according to the embodiment can predict the amount of heat input flowing from the plasma to the substrate W using the mathematical model. Therefore, the amount of heat input flowing from the plasma to the substrate W can be accurately measured.

In addition, a value of each of the coefficients of the mathematical model is determined by performing fitting using the data. As a result, the plasma processing system according to the embodiment can predict the amount of heat input flowing from the plasma to the substrate W using the mathematical model. Therefore, the amount of heat input flowing from the plasma to the substrate W can be accurately measured.

In addition, in the main body portion 111, the placement surface is divided into a plurality of areas. The cooling mechanism is provided in all of the areas of the main body portion 111. The heater HT is provided for each of the areas of the main body portion 111. The temperature sensor TS is provided for each of the areas of the main body portion 111, and measures the temperature of the main body portion 111 for each of the areas. The acquisition unit 121 periodically acquires the temperature of the cooling mechanism, and the amount of heat generated by the heater HT and the temperature of the main body portion 111 in each of the areas. The prediction unit 123 predicts the amount of heat input flowing from the plasma to the substrate W in each of the areas A using the calculation formula based on the temperature of the cooling mechanism acquired by the acquisition unit 121, the amount of heat generated by the heater HT and the temperature of the main body portion 111 in each of the areas, the first-order time derivative of the temperature of the main body portion 111 in each of the areas, and the first or higher-order time derivative of the temperature of the cooling mechanism. As a result, the plasma processing system according to the embodiment can measure the amount of heat input flowing from the plasma to the substrate W in each of the areas A.

In addition, the calculation formula is a mathematical model for calculating the amount of heat input flowing from the plasma to the substrate W in each of the areas by multiplying the amounts of heat generated by the heaters HT in the area and another area, the temperature of the main body portion 111, the temperature of the cooling mechanism, the first-order time derivative of the temperature of the main body portion 111, the first-order time derivative of the temperature of the cooling mechanism, and the second-order time derivative of the temperature of the cooling mechanism by coefficients, respectively, and adding the obtained values. A value of each of the coefficients of the mathematical model is determined using predetermined data representing a relationship between the amount of heat input flowing from the plasma to the substrate W in each of the areas, the amount of heat generated by the heater HT, the temperature of the main body portion 111, the temperature of the cooling mechanism, the first-order time derivative of the temperature of the main body portion 111, the first-order time derivative of the temperature of the cooling mechanism, and the second-order time derivative of the temperature of the cooling mechanism. As a result, the plasma processing system according to the embodiment can predict the amount of heat input flowing from the plasma to the substrate W in each of the areas A in consideration of heat transfer to and from another area A using the mathematical model.

In addition, a value of each of the coefficients of the mathematical model is determined by performing fitting using the data. As a result, the plasma processing system according to the embodiment can predict the amount of heat input flowing from the plasma to the substrate W in each of the areas A using the mathematical model. Therefore, the amount of heat input flowing from the plasma to the substrate W in each of the areas A can be predicted.

In addition, the calculation formula is a mathematical model for calculating the amount of heat input in each of the areas by multiplying the amounts of heat generated by the heaters HT in the area and all of the other areas, the temperature of the main body portion 111, the temperature of the cooling mechanism, the first-order time derivative of the temperature of the main body portion 111, the first-order time derivative of the temperature of the cooling mechanism, and the second-order time derivative of the temperature of the cooling mechanism by coefficients, respectively, and adding the obtained values. As a result, the plasma processing system according to the embodiment can predict the amount of heat input flowing from the plasma to the substrate W in each of the areas A in consideration of heat transfer to and from all of the other areas A using the mathematical model.

In addition, the cooling mechanism is a flow path formed to pass through all of the areas of the main body portion 111 and through which the coolant flows. The acquisition unit 121 acquires the temperature of the coolant flowing into the flow path. In addition, the plasma processing system according to the embodiment further includes the correction unit 122. The correction unit 122 corrects the temperature of the coolant acquired by the acquisition unit 121, to the temperature of the coolant in each of the areas along the flow path. The prediction unit 123 predicts the amount of heat input in each of the areas using the calculation formula based on the temperature of the coolant in each of the areas corrected by the correction unit 122, the amount of heat generated by the heater HT and the temperature of the main body portion 111 in each of the areas that are acquired by the acquisition unit 121, the first-order time derivative of the temperature of the cooling mechanism in each of the areas, the second-order time derivative of the temperature of the cooling mechanism, and the first-order time derivative of the temperature of the main body portion 111. As a result, the plasma processing system according to the embodiment can predict the amount of heat input flowing from the plasma to the substrate W in each of the areas A using the temperature of the coolant in each of the areas A. Therefore, the amount of heat input flowing from the plasma to the substrate W in each of the areas A can be accurately measured.

### Second Embodiment

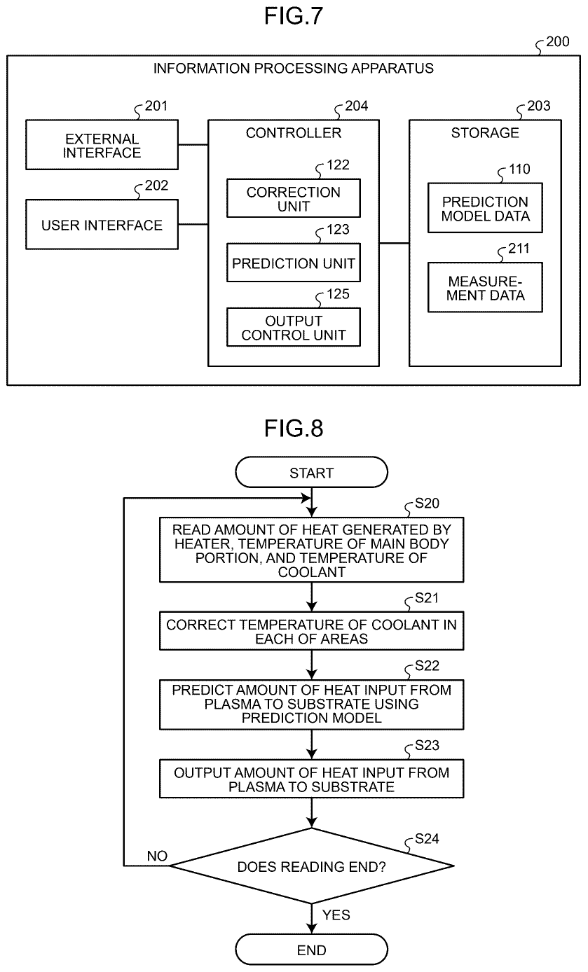

Next, a second embodiment will be described. In the second embodiment, a case where the amount of heat input from the plasma to the substrate W is predicted by an information processing apparatus will be described. FIG. 7 is a block diagram illustrating a schematic configuration of an information processing apparatus 200 according to the second embodiment. The information processing apparatus 200 according to the second embodiment has partially the same configuration and functions as those of the control unit 100 according to the first embodiment. Therefore, the same portions are represented by the same reference numerals, the description thereof will be omitted, and different portions will be mainly described.

The information processing apparatus 200 is, for example, a computer. The information processing apparatus 200 includes an external interface 201, a user interface 202, a storage 203, and a controller 204.

The external interface 201 is an interface through which various types of data are input and output. For example, the external interface 201 is connected to a network such that various types of data are input to and output from an external apparatus. The user interface 202 is configured with a keyboard with which a user such as a process manager performs an input operation of a command, a display that can display various types of information, and the like.

The storage 203 stores a control program (software) and various programs for implementing various processes to be performed under the control of the controller 204. In addition, the storage 203 stores various types of data used for the programs to be executed by the controller 204. For example, the storage 203 stores the above-described prediction model data 110 and measurement data 211. The programs and data may be used in a state of being stored in a computer-readable recording medium (for example, a hard disk, an optical disk such as a DVD, a flexible disk, or a semiconductor memory). In addition, the programs and data can also be used online by being transmitted as necessary from another apparatus through, for example, a dedicated line.

The prediction model data 110 is data storing a prediction model for predicting an amount of heat input from the plasma to the substrate W based on the amount of heat generated by the heater HT, the temperature of the main body portion 111, the temperature of the coolant, a first-order time derivative of the temperature of the main body portion 111, and a first or higher-order time derivative of the temperature of the coolant. For example, the prediction model stores Expression (1) where the coefficients a_{1,1} to a_{n,n}, b_{1,1} to b_{n,n}, c_{1,1} to c_{n,n}, d_{1,1} to d_{n,n}, e_{1,1} to e_{n,n}, and f_{1,1} to f_{n,n} are set.

The measurement data 211 is data obtained by periodically measuring the amount of heat generated by each of the heaters HT, the temperature of the main body portion 111, and the temperature of the coolant in the plasma processing apparatus 1 during the plasma processing. In the present embodiment, the measurement data 211 stores the measured time, the temperature of the coolant, and the amount of heat generated by the heater HT and the temperature of the main body portion 111 in each of the areas A.

The controller 204 includes a processor such as a CPU or an MPU and controls the information processing apparatus 200. The controller 204 includes an internal memory for storing the programs and data, reads the control program stored in the storage 203, and executes the processing of the read control program. The controller 204 functions as various processing units by the operation of the control program. For example, the controller 204 includes the above-described functions of the correction unit 122, the prediction unit 123, and the output control unit 125. In the present embodiment, an example in which the controller 204 has the functions of the correction unit 122, the prediction unit 123, and the output control unit 125 will be described. However, the functions of the correction unit 122, the prediction unit 123, and the output control unit 125 may be distributed and implemented by a plurality of controllers.

The prediction unit 123 predicts the amount of heat input from the plasma to the substrate W for each of the areas A using the prediction model stored in the prediction model data 110. For example, the prediction unit 123 reads the amount of heat generated by each of the heaters HT, the temperature of the main body portion 111, and the temperature of the coolant from the measurement data 211 in order of the measured time.

The correction unit 122 corrects the read temperature of the coolant to the temperature of the coolant in each of the areas A in response to temperature increase along the flow path 1110a of the plasma processing apparatus 1.

The prediction unit 123 predicts the amount of heat input from the plasma to the substrate W for each of the areas A based on the temperature of the coolant in each of the areas A corrected by the correction unit 122, the read amount of heat generated by the heater HT in each of the areas A, and the temperature of the main body portion 111. For example, the prediction unit 123 predicts the amount of heat input in each of the areas A using Expression (1) based on the temperature of the coolant in each of the areas A, the amount of heat generated by the heater HT, the temperature of the main body portion 111, the first-order time derivative of the temperature of the main body portion 111, the first-order time derivative of the temperature of the coolant, and the second-order time derivative of the temperature of the coolant.

The output control unit 125 performs various controls to output the amount of heat input from the plasma to the substrate W in each of the areas A, which is predicted by the prediction unit 123. For example, the output control unit 125 controls the user interface 202 to output information based on the amount of heat input from the plasma to the substrate W in each of the areas A, which is predicted by the prediction unit 123. For example, the output control unit 125 controls the user interface 202 to display an image representing a distribution of the amount of heat input in each of the areas A on the substrate W.

In addition, for example, the output control unit 125 outputs data regarding the amount of heat input from the plasma to the substrate W in each of the areas A, which is predicted by the prediction unit 123, to an external terminal device via a network (not illustrated). In addition, for example, the output control unit 125 controls the storage 203 to store the data regarding the amount of heat input from the plasma to the substrate W in each of the areas A, which is predicted by the prediction unit 123.

### Specific Example of Flow of Prediction Processing

Next, a specific example of a flow of prediction processing in a prediction method according to the second embodiment will be described. FIG. 8 is a flowchart illustrating an example of the flow of the prediction processing according to the second embodiment. The prediction processing according to the second embodiment is performed when a predetermined operation for instructing the start of the prediction processing is performed on the user interface 202.

The prediction unit 123 reads the amount of heat generated by each of the heaters HT, the temperature of the main body portion 111, and the temperature of the coolant from the measurement data 211 in order of the measured time (Step S20).

The correction unit 122 corrects the read temperature of the coolant to the temperature of the coolant in each of the areas A in response to temperature increase along the flow path 1110a of the plasma processing apparatus 1 (Step S21).

The prediction unit 123 predicts the amount of heat input from the plasma to the substrate W for each of the areas A using the prediction model stored in the prediction model data 110 (Step S22). For example, the prediction unit 123 predicts the amount of heat input in each of the areas A using Expression (1) based on the temperature of the coolant in each of the areas A, the amount of heat generated by the heater HT, the temperature of the main body portion 111, the first-order time derivative of the temperature of the main body portion 111, the first-order time derivative of the temperature of the coolant, and the second-order time derivative of the temperature of the coolant.

As a result, the information processing apparatus 200 according to the second embodiment can measure the amount of heat input flowing from the plasma to each of the areas A of the substrate W in the plasma processing of the plasma processing apparatus 1.

The output control unit 125 performs various controls to output the amount of heat input from the plasma to the substrate W in each of the areas A, which is predicted by the prediction unit 123 (Step S23). For example, the output control unit 125 controls the user interface 202 to display an image representing a distribution of the amount of heat input in each of the areas A on the substrate W.

As a result, a user such as a process manager can grasp the state of the plasma processing by checking the image displayed on the user interface 202. For example, the user can grasp the density distribution of the plasma in the plasma processing of the plasma processing apparatus 1 from the image representing the distribution of the amount of heat input in each of the areas A.

The prediction unit 123 determines whether reading of data from the measurement data 211 ends (Step S24). When the reading of data does not end (Step S24: No), the process proceeds to Step S20 described above. When the reading of data ends (Step S24: Yes), the process ends.

As described above, the information processing apparatus 200 according to the second embodiment includes the storage 203 and the prediction unit 123. The storage 203 stores the measurement data 211 obtained by periodically measuring the amount of heat generated by the heater HT, the temperature of the main body portion 111, and the temperature of the cooling mechanism of the plasma processing apparatus 1 that performs plasma processing on the substrate W placed on the main body portion 111 while cooling the main body portion 111 with the cooling mechanism (the coolant, the flow path 1110a, or the like) provided in the main body portion 111 (the stage) on which the substrate W is placed and heating the main body portion 111 with the heater HT (the heating mechanism) provided between the placement surface of the main body portion 111 on which the substrate W is placed and the cooling mechanism. The prediction unit 123 predicts the amount of heat input flowing from the plasma to the substrate W using the calculation formula (for example, Expression (1)) based on the amount of heat generated by the heater HT, the temperature of the main body portion 111, and the temperature of the cooling mechanism that are stored in the measurement data 211, the first-order time derivative of the temperature of the main body portion 111, and the first or higher-order time derivative of the temperature of the cooling mechanism, in which the calculation formula predicts the amount of heat input flowing from the plasma to the substrate W based on the amount of heat generated by the heater HT, the temperature of the main body portion 111, the temperature of the cooling mechanism, the first-order time derivative of the temperature of the main body portion 111, and the first or higher-order time derivative of the temperature of the cooling mechanism. As a result, the information processing apparatus 200 according to the second embodiment can measure the amount of heat input flowing from the plasma to the substrate W.

The embodiments disclosed herein are merely examples in all aspects and should not be construed to limit the scope of the present invention. Indeed, the above-described embodiments may be implemented in various forms. In addition, the above-described embodiments may be omitted, substituted, or changed in various forms without departing from the scope and the spirit of the appended claims.

Regarding the above-described embodiments, the following supplementary notes are further disclosed.

According to the present disclosure, the amount of heat input flowing from the plasma to the substrate can be measured.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

In connection with the above embodiment, the following notes are further disclosed.

### (Note 1)

A plasma processing apparatus comprising:
a stage on which a substrate is placed;
a chamber in which the stage is provided and plasma is generated to perform plasma processing on the substrate placed on the stage;
a cooling mechanism provided in the stage and configured to cool the stage;
a heating mechanism provided between a placement surface of the stage on which the substrate is placed and the cooling mechanism and configured to control an amount of heat generated and to heat the stage;
a measurement unit configured to measure a temperature of the stage;
an acquisition unit configured to periodically acquire an amount of heat generated by the heating mechanism, a temperature of the stage, and a temperature of the cooling mechanism; and
a prediction unit configured to predict an amount of heat input flowing from the plasma to the substrate using a calculation formula based on the amount of heat generated by the heating mechanism, the temperature of the stage, and the temperature of the cooling mechanism that are acquired by the acquisition unit, a first-order time derivative of the temperature of the stage, and a first or higher-order time derivative of the temperature of the cooling mechanism, in which the calculation formula predicts an amount of heat input flowing from the plasma to the substrate based on the amount of heat generated by the heating mechanism, the temperature of the stage, the temperature of the cooling mechanism, the first-order time derivative of the temperature of the stage, and the first or higher-order time derivative of the temperature of the cooling mechanism.

### (Note 2)

The plasma processing apparatus according to note 1, wherein
the calculation formula is a prediction model for predicting an amount of heat input flowing from the plasma to the substrate based on the amount of heat generated by the heating mechanism, the temperature of the stage, the temperature of the cooling mechanism, the first-order time derivative of the temperature of the stage, and the first or higher-order time derivative of the temperature of the cooling mechanism.

### (Note 3)

The plasma processing apparatus according to note 1 or 2, wherein
the calculation formula is a mathematical model for calculating an amount of heat input flowing from the plasma to the substrate by multiplying the amount of heat generated by the heating mechanism, the temperature of the stage, the temperature of the cooling mechanism, the first-order time derivative of the temperature of the stage, the first-order time derivative of the temperature of the cooling mechanism, and the second-order time derivative of the temperature of the cooling mechanism by coefficients, respectively, and adding the obtained values, and
a value of each of the coefficients of the mathematical model is determined using predetermined data representing a relationship between the amount of heat input flowing from the plasma to the substrate, the amount of heat generated by the heating mechanism, the temperature of the stage, the temperature of the cooling mechanism, the first-order time derivative of the temperature of the stage, the first-order time derivative of the temperature of the cooling mechanism, and the second-order time derivative of the temperature of the cooling mechanism.

### (Note 4)

The plasma processing apparatus according to note 3, wherein
a value of each of the coefficients of the mathematical model is determined by performing fitting using the data.

### (Note 5)

The plasma processing apparatus according to note 1, wherein
in the stage, the placement surface is divided into a plurality of areas,
the cooling mechanism is provided in all of the areas of the stage,
the heating mechanism is provided for each of the areas of the stage,
the measurement unit is provided for each of the areas of the stage and measures the temperature of the stage for each of the areas,
the acquisition unit periodically acquires the temperature of the cooling mechanism and, for each of the areas, the amount of heat generated by the heating mechanism and the temperature of the stage, and
the prediction unit predicts an amount of heat input flowing from the plasma to the substrate for each of the areas using the calculation formula based on the temperature of the cooling mechanism acquired by the acquisition unit, the amount of heat generated by the heating mechanism and the temperature of the stage for each of the areas, the first-order time derivative of the temperature of the stage for each of the areas, and the first or higher-order time derivative of the temperature of the cooling mechanism.

### (Note 6)

The plasma processing apparatus according to note 5, wherein
the calculation formula is a mathematical model for calculating an amount of heat input flowing from the plasma to the substrate for each of the areas by multiplying the amounts of heat generated by the heating mechanism for the area and another area, the temperature of the stage, the temperature of the cooling mechanism, the first-order time derivative of the temperature of the stage, a first-order time derivative of the temperature of the cooling mechanism, and a second-order time derivative of the temperature of the cooling mechanism by coefficients, respectively, and adding the obtained values, and
a value of each of the coefficients of the mathematical model is determined using predetermined data representing a relationship between the amount of heat input flowing from the plasma to the substrate for each of the areas, the amount of heat generated by the heating mechanism, the temperature of the stage, the temperature of the cooling mechanism, the first-order time derivative of the temperature of the stage, the first-order time derivative of the temperature of the cooling mechanism, and the second-order time derivative of the temperature of the cooling mechanism.

### (Note 7)

The plasma processing apparatus according to note 6, wherein
a value of each of the coefficients of the mathematical model is determined by performing fitting using the data.

### (Note 8)

The plasma processing apparatus according to note 6 or 7, wherein
the calculation formula is a mathematical model for calculating the amount of heat input in each of the areas by multiplying the amounts of heat generated by the heating mechanism for the area and all of the other areas, the temperature of the stage, the temperature of the cooling mechanism, the first-order time derivative of the temperature of the stage, the first-order time derivative of the temperature of the cooling mechanism, and the second-order time derivative of the temperature of the cooling mechanism by coefficients, respectively, and adding the obtained values.

### (Note 9)

The plasma processing apparatus according to any one of notes 5 to 8, wherein
the cooling mechanism is a flow path formed to pass through all of the areas of the stage and through which a coolant flows, and
the acquisition unit acquires a temperature of the coolant flowing into the flow path.

### (Note 10)

The plasma processing apparatus according to note 9, further comprising:
a correction unit configured to correct the temperature of the coolant acquired by the acquisition unit to a temperature of the coolant in each of the areas along the flow path, wherein
the prediction unit predicts the amount of heat input in each of the areas using the calculation formula based on the temperature of the coolant for each of the areas corrected by the correction unit, the amount of heat generated by the heating mechanism and the temperature of the stage for each of the areas that are acquired by the acquisition unit, and, for each of the areas, the first-order time derivative of the temperature of the cooling mechanism, the second-order time derivative of the temperature of the cooling mechanism, and the first-order time derivative of the temperature of the stage.

### (Note 11)

A prediction method for a plasma processing apparatus including
a stage on which a substrate is placed,
a chamber in which the stage is provided and plasma is generated to perform plasma processing on the substrate placed on the stage,
a cooling mechanism provided in the stage and configured to cool the stage,
a heating mechanism provided between a placement surface of the stage on which the substrate is placed and the cooling mechanism and configured to control an amount of heat generated and to heat the stage, and
a measurement unit configured to measure a temperature of the stage,
the prediction method comprising:
a) a step of periodically acquiring an amount of heat generated by the heating mechanism, a temperature of the stage, and a temperature of the cooling mechanism; and
b) a step of predicting an amount of heat input flowing from the plasma to the substrate using a calculation formula based on the amount of heat generated by the heating mechanism, the temperature of the stage, and the temperature of the cooling mechanism that are acquired, a first-order time derivative of the temperature of the stage, and a first or higher-order time derivative of the temperature of the cooling mechanism, in which the calculation formula predicts an amount of heat input flowing from the plasma to the substrate based on the amount of heat generated by the heating mechanism, the temperature of the stage, the temperature of the cooling mechanism, the first-order time derivative of the temperature of the stage, and the first or higher-order time derivative of the temperature of the cooling mechanism.

### (Note 12)

A prediction program for a plasma processing apparatus including
a stage on which a substrate is placed,
a chamber in which the stage is provided and plasma is generated to perform plasma processing on the substrate placed on the stage,
a cooling mechanism provided in the stage and configured to cool the stage,
a heating mechanism provided between a placement surface of the stage on which the substrate is placed and the cooling mechanism and configured to control an amount of heat generated and to heat the stage, and
a measurement unit configured to measure a temperature of the stage,
the prediction program causing a computer to execute:
a) a step of periodically acquiring an amount of heat generated by the heating mechanism, a temperature of the stage, and a temperature of the cooling mechanism; and
b) a step of predicting an amount of heat input flowing from the plasma to the substrate using a calculation formula based on the amount of heat generated by the heating mechanism, the temperature of the stage, and the temperature of the cooling mechanism that are acquired, a first-order time derivative of the temperature of the stage, and a first or higher-order time derivative of the temperature of the cooling mechanism, in which the calculation formula predicts an amount of heat input flowing from the plasma to the substrate based on the amount of heat generated by the heating mechanism, the temperature of the stage, the temperature of the cooling mechanism, the first-order time derivative of the temperature of the stage, and the first or higher-order time derivative of the temperature of the cooling mechanism.

### (Note 13)

An information processing apparatus comprising:
a storage configured to store measurement data obtained by periodically measuring an amount of heat generated by a heating mechanism, a temperature of a stage, and a temperature of a cooling mechanism of a plasma processing apparatus that performs plasma processing on a substrate placed on the stage while cooling the stage with the cooling mechanism provided on the stage on which the substrate is placed and heating the stage with the heating mechanism provided between a placement surface of the stage on which the substrate is placed and the cooling mechanism; and
a prediction unit configured to predict an amount of heat input flowing from the plasma to the substrate using a calculation formula based on the amount of heat generated by the heating mechanism, the temperature of the stage, and the temperature of the cooling mechanism that are stored in the measurement data, a first-order time derivative of the temperature of the stage, and a first or higher-order time derivative of the temperature of the cooling mechanism, in which the calculation formula predicts an amount of heat input flowing from the plasma to the substrate based on the amount of heat generated by the heating mechanism, the temperature of the stage, the temperature of the cooling mechanism, the first-order time derivative of the temperature of the stage, and the first or higher-order time derivative of the temperature of the cooling mechanism.

What is claimed is:

1. A plasma processing apparatus comprising:
a stage configured to support a substrate;
a chamber including the stage and configured for plasma generation to perform plasma processing on the substrate placed on the stage;
a cooler in the stage and configured to cool the stage;
a heater between a placement surface of the stage on which the substrate is placed and the cooler and configured to control an amount of heat generated to heat the stage;
a temperature sensor configured to measure a temperature of the stage; and
a controller configured to
periodically acquire an amount of heat generated by the heater, a temperature of the stage, and a temperature of the cooler; and
predict an amount of heat input flowing from the plasma to the substrate using a calculation formula based on the amount of heat generated by the heater, the temperature of the stage, and the temperature of the cooler that are acquired, a first-order time derivative of the temperature of the stage, and a first or higher-order time derivative of the temperature of the cooler, in which the calculation formula predicts an amount of heat input flowing from the plasma to the substrate based on the amount of heat generated by the heater, the temperature of the stage, the temperature of the cooler, the first-order time derivative of the temperature of the stage, and the first or higher-order time derivative of the temperature of the cooler.

2. The plasma processing apparatus according to claim 1, wherein
the calculation formula is a prediction model for predicting an amount of heat input flowing from the plasma to the substrate based on the amount of heat generated by the heater, the temperature of the stage, the temperature of the cooler, the first-order time derivative of the temperature of the stage, and the first or higher-order time derivative of the temperature of the cooler.

3. The plasma processing apparatus according to claim 1, wherein
the calculation formula is a mathematical model for calculating an amount of heat input flowing from the plasma to the substrate by multiplying the amount of heat generated by the heater, the temperature of the stage, the temperature of the cooler, the first-order time derivative of the temperature of the stage, the first-order time derivative of the temperature of the cooler, and a second-order time derivative of the temperature of the cooler by coefficients, respectively, and adding the obtained values, and
a value of each of the coefficients of the mathematical model is determined using predetermined data representing a relationship between the amount of heat input flowing from the plasma to the substrate, the amount of heat generated by the heater, the temperature of the stage, the temperature of the cooler, the first-order time derivative of the temperature of the stage, the first-order time derivative of the temperature of the cooler, and the second-order time derivative of the temperature of the cooler.

4. The plasma processing apparatus according to claim 3, wherein
a value of each of the coefficients of the mathematical model is determined by performing fitting using the data.

5. The plasma processing apparatus according to claim 1, wherein
in the stage, the placement surface is divided into a plurality of areas,
the cooler is in all of the areas of the stage,
the heater is at each of the areas of the stage,
the temperature sensor is configured to measure the temperature of the stage for each of the areas, and
the controller is configured to
periodically acquire the temperature of the cooler and, for each of the areas, the amount of heat generated by the heater and the temperature of the stage, and
predict an amount of heat input flowing from the plasma to the substrate for each of the areas using the calculation formula based on the temperature of the cooler acquired, the amount of heat generated by the heater and the temperature of the stage for each of the areas, the first-order time derivative of the temperature of the stage for each of the areas, and the first or higher-order time derivative of the temperature of the cooler.

6. The plasma processing apparatus according to claim 5, wherein
the calculation formula is a mathematical model for calculating an amount of heat input flowing from the plasma to the substrate for each of the areas by multiplying the amounts of heat generated by the heater for the area and another area, the temperature of the stage, the temperature of the cooler, the first-order time derivative of the temperature of the stage, a first-order time derivative of the temperature of the cooler, and a second-order time derivative of the temperature of the cooler by coefficients, respectively, and adding the obtained values, and
a value of each of the coefficients of the mathematical model is determined using predetermined data representing a relationship between the amount of heat input flowing from the plasma to the substrate for each of the areas, the amount of heat generated by the heater, the temperature of the stage, the temperature of the cooler, the first-order time derivative of the temperature of the stage, the first-order time derivative of the temperature of the cooler, and the second-order time derivative of the temperature of the cooler.

7. The plasma processing apparatus according to claim 6, wherein
a value of each of the coefficients of the mathematical model is determined by performing fitting using the data.

8. The plasma processing apparatus according to claim 6, wherein
the calculation formula is a mathematical model for calculating the amount of heat input in each of the areas by multiplying the amounts of heat generated by the heater for the area and all of the other areas, the temperature of the stage, the temperature of the cooler, the first-order time derivative of the temperature of the stage, the first-order time derivative of the temperature of the cooler, and the second-order time derivative of the temperature of the cooler by coefficients, respectively, and adding the obtained values.

9. The plasma processing apparatus according to claim 5, wherein
the cooler is a flow path configured to pass through all of the areas of the stage and configured to enable a coolant to flow, and
the controller is configured to acquire a temperature of the coolant flowing into the flow path.

10. The plasma processing apparatus according to claim 9, wherein
the controller is further configured to correct the temperature of the coolant acquired to a temperature of the coolant in each of the areas along the flow path, and
predict the amount of heat input in each of the areas using the calculation formula based on the temperature of the coolant for each of the areas corrected, the amount of heat generated by the heater and the temperature of the stage for each of the areas that are acquired, and, for each of the areas, the first-order time derivative of the temperature of the cooler, a second-order time derivative of the temperature of the cooler, and the first-order time derivative of the temperature of the stage.

11. A prediction method for a plasma processing apparatus, the plasma apparatus including
a stage configured to support a substrate,
a chamber including the stage and configured for plasma generation to perform plasma processing on the substrate placed on the stage,
a cooler in the stage and configured to cool the stage,
a heater between a placement surface of the stage on which the substrate is placed and the cooler and configured to control an amount of heat generated and to heat the stage, and
a temperature sensor configured to measure a temperature of the stage,
the prediction method comprising:
periodically acquiring an amount of heat generated by the heater, a temperature of the stage, and a temperature of the cooler; and
predicting an amount of heat input flowing from the plasma to the substrate using a calculation formula based on the amount of heat generated by the heater, the temperature of the stage, and the temperature of the cooler that are acquired, a first-order time derivative of the temperature of the stage, and a first or higher-order time derivative of the temperature of the cooler, in which the calculation formula predicts an amount of heat input flowing from the plasma to the substrate based on the amount of heat generated by the heater, the temperature of the stage, the temperature of the cooler, the first-order time derivative of the temperature of the stage, and the first or higher-order time derivative of the temperature of the cooler.

12. A non-transitory computer readable recording medium storing a prediction program for a plasma processing apparatus, the plasma processing apparatus including
a stage configured to support a substrate,
a chamber including the stage and configured for plasma generation to perform plasma processing on the substrate placed on the stage,
a cooler in the stage and configured to cool the stage,
a heater between a placement surface of the stage on which the substrate is placed and the cooler and configured to control an amount of heat generated and to heat the stage, and
a temperature sensor configured to measure a temperature of the stage, and
the prediction program causing a computer to execute operations of:
periodically acquiring an amount of heat generated by the heater, a temperature of the stage, and a temperature of the cooler; and
predicting an amount of heat input flowing from the plasma to the substrate using a calculation formula based on the amount of heat generated by the heater, the temperature of the stage, and the temperature of the cooler that are acquired, a first-order time derivative of the temperature of the stage, and a first or higher-order time derivative of the temperature of the cooler, in which the calculation formula predicts an amount of heat input flowing from the plasma to the substrate based on the amount of heat generated by the heater, the temperature of the stage, the temperature of the cooler, the first-order time derivative of the temperature of the stage, and the first or higher-order time derivative of the temperature of the cooler.

13. An information processing apparatus comprising:
a storage configured to store measurement data obtained by periodically measuring an amount of heat generated by a heater, a temperature of a stage, and a temperature of a cooler of a plasma processing apparatus that performs plasma processing on a substrate placed on the stage while cooling the stage with the cooler on the stage on which the substrate is placed and heating the stage with the heater that is between a placement surface of the stage on which the substrate is placed and the cooler; and
a controller configured to predict an amount of heat input flowing from the plasma to the substrate using a calculation formula based on the amount of heat generated by the heater, the temperature of the stage, and the temperature of the cooler that are stored in the measurement data, a first-order time derivative of the temperature of the stage, and a first or higher-order time derivative of the temperature of the cooler, in which the calculation formula predicts an amount of heat input flowing from the plasma to the substrate based on the amount of heat generated by the heater, the temperature of the stage, the temperature of the cooler, the first-order time derivative of the temperature of the stage, and the first or higher-order time derivative of the temperature of the cooler.
